(19) United States
(12) Patent Application Publication
(10) Pub. No.: US 2024/0423053 A1
(43) Pub. Date: Dec. 19, 2024

(54) DISPLAY DEVICE

(71) Applicant: SHARP KABUSHIKI KAISHA, Sakai City (JP)

(72) Inventor: YOSHIHIRO UETA, Sakai City (JP)

(21) Appl. No.: 18/741,264

(22) Filed: Jun. 12, 2024

(30) Foreign Application Priority Data
Jun. 16, 2023 (JP) 2023-099524

(51) Int. Cl. H10K 59/32

(52) U.S. Cl. CPC H10K 59/32

(57) ABSTRACT

A display device includes the following: a first light-emitting element having a first emission region; a second light-emitting element adjacent to the first light-emitting element, and having a second emission region; and a third light-emitting element adjacent to both of the first light-emitting element and the second light-emitting element, and having a third emission region. In a plan view, any part of the first emission region, any part of the second emission region, and any part of the third emission region are in positions that are 3-fold rotationally symmetric with each other. Between the first emission region and the second emission region, between the second emission region and the third emission region, and between the third emission region and the first emission region, two sides facing each other in the plan view extend in a direction where the two sides intersect.

### CROSS-REFERENCE TO RELATED APPLICATION

The present application claims priority from Japanese Application JP2023-099524, filed on Jun. 16, 2023, the content of which is hereby incorporated by reference into this application.

### BACKGROUND OF THE INVENTION

### Field of the Invention

The present disclosure relates to a display device including a plurality of light-emitting elements.

### Description of the Related Art

Japanese Unexamined Patent Application Publication No. 2018-185515 discloses a micro-LED display device with a micro-LED provided for each subpixel.

Like the micro-LED display device described in Japanese Unexamined Patent Application Publication No. 2018-185515, a display device with a light-emitting element provided for each subpixel has, in some cases, a stray light phenomenon, where light emitted from a certain subpixel propagates to another subpixel. Stray light can degrade the display quality of a display device.

### SUMMARY OF THE INVENTION

A display device according to one aspect of the present disclosure includes the following: a first light-emitting element having a first emission region; a second light-emitting element adjacent to the first light-emitting element, and having a second emission region; and a third light-emitting element adjacent to both of the first light-emitting element and the second light-emitting element, and having a third emission region. In a plan view, any part of the first emission region, any part of the second emission region, and any part of the third emission region are in positions that are 3-fold rotationally symmetric with each other. Between the first emission region and the second emission region, between the second emission region and the third emission region, and between the third emission region and the first emission region, two sides facing each other in the plan view extend in a direction where the two sides intersect.

The aspect reduces stray light propagation between light-emitting elements and improves display quality.

### BRIEF DESCRIPTION OF THE DRAWINGS

FIG. 1 is an enlarged plan view of a pixel of a display device according to a first embodiment;

FIG. 2 is a schematic plan view of the display device according to the first embodiment;

FIG. 3 is an enlarged plan view of the display device according to the first embodiment;

FIG. 4 is a schematic sectional side view of the display device according to the first embodiment;

FIG. 5 schematically illustrates a stacked structure of a light-emitting element according to the first embodiment;

FIG. 6 is another schematic sectional side view of the display device according to the first embodiment;

FIG. 7 is a flowchart showing a method for manufacturing the display device according to the first embodiment;

FIG. 8 is sectional views of the display device according to the first embodiment in the process of being manufactured;

FIG. 9 is other sectional views of the display device according to the first embodiment in the process of being manufactured;

FIG. 10 is a graph showing the relationship between distance from the center of an emission region and luminance, in a display device according to an example, and graphs showing the relationship between distance from the center of an emission region and luminance, in display devices according to comparative examples;

FIG. 11 is an enlarged plan view of a pixel of a display device according to a second embodiment;

FIG. 12 is a schematic sectional side view of a display device according to a third embodiment;

FIG. 13 is an enlarged plan view of a pixel of a display device according to a fourth embodiment;

FIG. 14 is an enlarged plan view of a display device according to a fifth embodiment;

FIG. 15 is a schematic sectional view of a wearable device according to the fifth embodiment; and

FIG. 16 is a schematic sectional view of another wearable device according to the fifth embodiment.

### DETAILED DESCRIPTION OF THE INVENTION

### First Embodiment

### Overview of Display Device

The embodiments of the present disclosure will be described with reference to the drawings. It is noted that like components will be denoted by the same signs throughout the drawings, and that their description will be omitted.

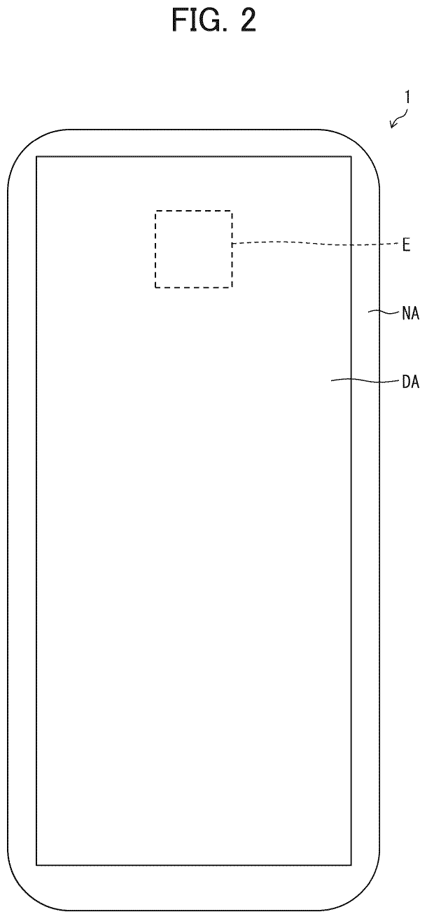

FIG. 2 is a schematic plan view of a display device 1 according to this embodiment. The display device 1 is a device that can be used for displays of a television set, a smartphone, and other things, or for wearable devices, such as an HMD, VR goggles, and AR goggles. The display device 1 includes a display section DA, and a frame section NA formed around the display section DA. The display device 1 controls light emission from each of a plurality of light-emitting elements, which will be described later on, formed in the display section DA to thus perform display in the display section DA. Drivers or other things for driving a plurality of respective light-emitting elements in the display section DA may be formed in the frame section NA.

### Arrangement of Pixels and Light-Emitting Elements of Display Device

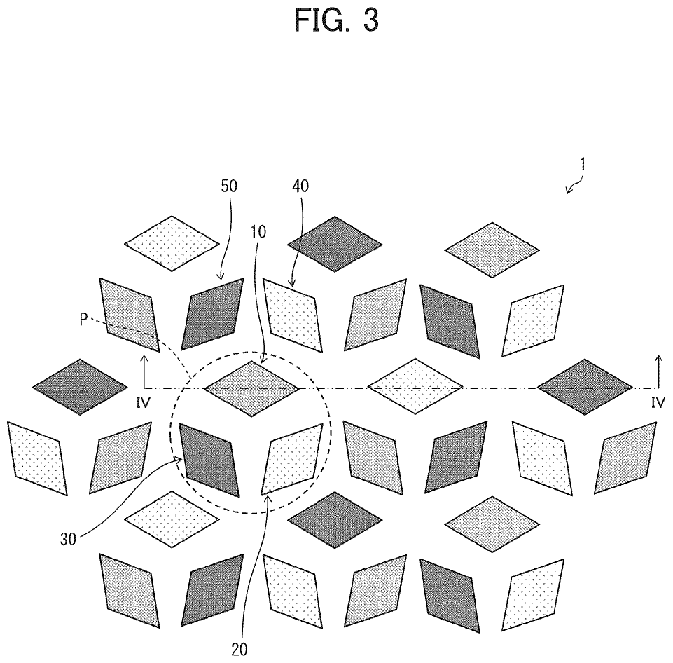

The display device 1 according to this embodiment will be detailed with reference to FIG. 3. FIG. 3 is an enlarged plan view of the display section DA of the display device 1; in particular, FIG. 3 is an enlarged plan view of a region E illustrated in FIG. 2. It is noted that the enlarged plan view of the display section DA of the display device 1 in the present disclosure including FIG. 3 is a view in which the emission regions of respective light-emitting elements, which will be described later on, are extracted in order to clearly show individual components.

The display device 1 includes the following light-emitting elements: a plurality of blue light-emitting elements 10, which are first light-emitting elements; a plurality of green light-emitting elements 20, which are second light-emitting elements; and a plurality of red light-emitting elements 30, which are third light-emitting elements. The display device 1 includes a plurality of pixels P each including a single blue light-emitting element 10, a single green light-emitting element 20, and a single red light-emitting element 30.

The blue light-emitting element 10 emits blue light, which is first light. The green light-emitting element 20 emits green light, which is second light. The red light-emitting element 30 emits red light, which is third light. The display device 1 individually drives each of the light-emitting elements of each pixel P, to individually extract blue light, green light, and red light from the pixel. Accordingly, the display device 1 performs full-color display in the display section DA.

The blue light-emitting element 10 in this embodiment is adjacent to the green light-emitting element 20 and red light-emitting element 30 included in the pixel P including the blue light-emitting element 10. Further, the blue light-emitting element 10 may be adjacent to a green light-emitting element 40 and a red light-emitting element 50 both included in a pixel P that is different from the pixel P including the blue light-emitting element 10. Here, the green light-emitting element 40 is a fourth light-emitting element, and the red light-emitting element 50 is a fifth light-emitting element. It is noted that the wording “two light-emitting elements are adjacent to each other” in the present disclosure means that no other light-emitting element is present between sides belonging to the respective emission regions of the two light-emitting elements and facing each other in plan view.

In this embodiment, the positional relationship of the blue light-emitting element 10, green light-emitting element 20, and red light-emitting element 30 in each pixel P may be different between two adjacent pixels P. Accordingly, the display device 1 prevents degradation in its display quality that results from a phenomenon where emission regions of the same light-emission color are visually recognized at the same period. Further, the individual light-emitting elements in this embodiment may be arranged in such a manner that the color of emitted light is different between two of the light-emitting elements adjacent to each other. Accordingly, the emission regions of the two adjacent light-emitting elements are coupled together apparently; consequently, the display device 1 prevents degradation in its display quality that results from substantial resolution reduction.

### Substate of Display Device

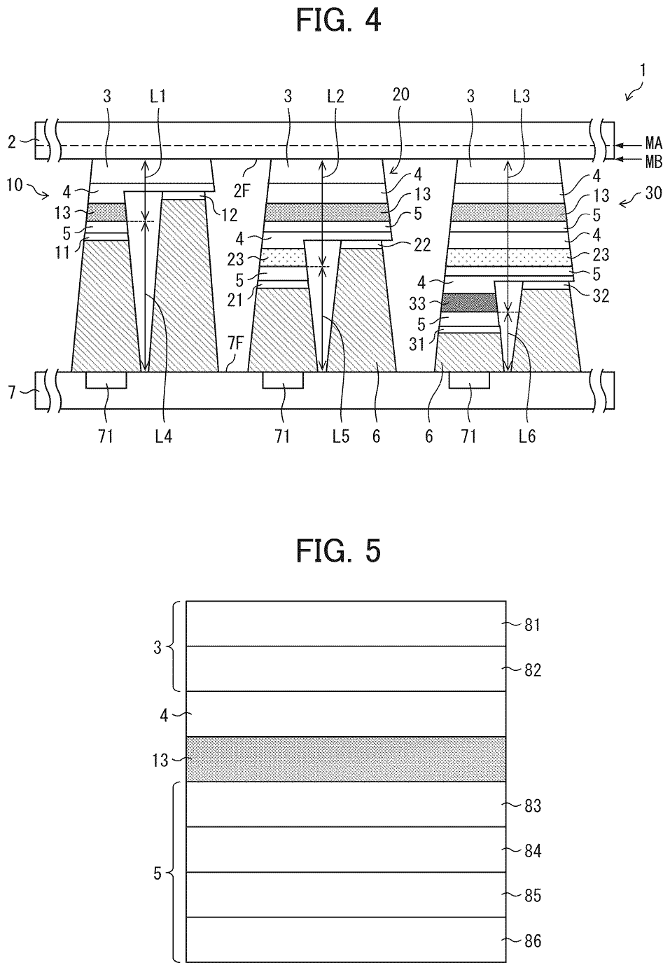

The structure of the display section DA of the display device 1 will be further detailed with reference to FIG. 4. FIG. 4 is a schematic sectional side view of the display device 1; in particular, FIG. 4 is a sectional view taken along line IV-IV in FIG. 3. In other words, FIG. 4 is a sectional side view taken along the blue light-emitting element 10, green light-emitting element 20, and red light-emitting element 30 of the display device 1.

As illustrated in FIG. 4, the display device 1 includes the following: a first substrate 2; a second substrate 7 facing the first substrate 1; and the blue light-emitting element 10, green light-emitting element 20, and red light-emitting element 30 between the first substrate 1 and second substrate 7. The first substrate 2 and the second substrate 7 are formed, for instance, across the display section DA and the frame section NA. It is noted that unless otherwise specified, the present disclosure will describe a direction from the first substrate 2 to the light-emitting elements as a “downward direction”, and a direction from the second substrate 7 to the light-emitting elements as an “upward direction”.

The first substrate 2 is a rigid substrate having light transparency and is, for instance, a sapphire substrate containing sapphire having a C-plane on a first surface 2F, which is located adjacently to the second substrate 7. The blue light-emitting element 10, the green light-emitting element 20, and the red light-emitting element 30 are located on the first surface 2F. The second substrate 7 includes pixel circuits 71 that drive the respective blue light-emitting element 10, green light-emitting element 20, and red light-emitting element 30 through a method that will be described later on. The display device 1 also includes a joining material 6 on a second surface 7F of the second substrate 7, which is located adjacently to the first substrate 2. The second substrate 7 is joined with the blue light-emitting element 10, green light-emitting element 20, and red light-emitting element 30 via the joining material 6. The first substrate 2 and the second substrate 7 may be joined together by a joining material or other things around each light-emitting element, such as in the frame section NA.

### Stacked Structure of Light-Emitting Element of Display Device

The blue light-emitting element 10, the green light-emitting element 20, and the red light-emitting element 30 include the following sequentially on the first substrate 2: an underlayer 3; an electron transport layer 4; a blue light-emitting layer 13, which is a first light-emitting layer; and a hole transport layer 5. The green light-emitting element 20 and the red light-emitting element 30 also include the following disposed on part of the lower surface of the hole transport layer 5 directly under the blue light-emitting layer 13, and sequentially disposed adjacently to the first substrate 2: the electron transport layer 4; a green light-emitting layer 23, which is a second light-emitting layer; and the hole transport layer 5. The red light-emitting element 30 furthermore includes the following disposed on part of the lower surface of the hole transport layer 5 directly under the green light-emitting layer 23, and sequentially disposed adjacently to the first substrate 2: the electron transport layer 4; a red light-emitting layer 33, which is a third light-emitting layer; and the hole transport layer 5.

The number of layers located between the blue light-emitting layer 13 and the first substrate 2, the number of layers located between the green light-emitting layer 23 and the first substrate 2, and the number of layers located between the red light-emitting layer 33 and the first substrate 2 are different from each other. Thus, a distance L1 from the blue light-emitting layer 13 to the first surface 2F of the first substrate 2, a distance L2 from the green light-emitting layer 23 to the first surface 2F, and a distance L3 from the red light-emitting layer 33 to the first surface 2F are different from each other. Further, the first surface 2F of the first substrate 2 and the second surface 7F of the second substrate 7 are parallel substantially. Hence, a distance L4 from the blue light-emitting layer 13 to the second surface 7F of the second substrate 7, a distance L5 from the green light-emitting layer 23 to the second surface 7F, and a distance L6 from the red light-emitting layer 33 to the second surface 7F are different from each other.

The stacked structure of each light-emitting element according to this embodiment will be detailed with reference to FIG. 5. FIG. 5 schematically illustrates the blue light-emitting element 10 with a stack of the underlayer 3 through the hole transport layer 5 extracted.

The underlayer 3 is a layer for lattice matching between the sapphire crystals of the first substrate 2, which is a sapphire substrate, and the crystals of a semiconductor of the electron transport layer 4, which will be described later on. The underlayer 3 includes a first buffer layer 81 and a second buffer layer 82 sequentially on the first substrate 2. The first buffer layer 81 contains a semiconductor crystal epitaxially grown on the first surface 2F at a low temperature of, for example, 600° C. or less; the first buffer layer 81 may contain, for example, a 40-nm-thick gallium nitride crystal. The second buffer layer 82 contains a semiconductor crystal epitaxially grown on the first buffer layer 81; the second buffer layer 82 may contain, for example, a 2-μm-thick non-doped gallium nitride crystal. The first buffer layer 81 and the second buffer layer 82 may be also formed between the electron transport layer 4 and the hole transport layer 5.

The electron transport layer 4 is a layer that transports electrons from a cathode, which will be described later on, to the light-emitting layer. The electron transport layer 4 contains an n-type semiconductor crystal epitaxially grown on the second buffer layer 82; the electron transport layer 4 may contain, for example, a 2-μm-thick gallium nitride crystal having a group 14 element, such as Si, as a dopant.

The hole transport layer 5 is a layer that transports holes from an anode, which will be described later on, to the light-emitting layer. The hole transport layer 5 includes, sequentially adjacently to the first substrate 2, a first p-type semiconductor layer 83, a second p-type semiconductor layer 84, a first n-type semiconductor layer 85, and a second n-type semiconductor layer 86.

Each of the first p-type semiconductor layer 83 and second p-type semiconductor layer 84 contains a p-type semiconductor crystal formed through epitaxial growth. For example, the first p-type semiconductor layer 83 may contain a 20-nm-thick aluminum gallium nitride crystal, and the second p-type semiconductor layer 84 may contain a 120-nm-thick gallium nitride crystal. The first p-type semiconductor layer 83 and the second p-type semiconductor layer 84 may have a group 2 element, such as Mg, as a dopant.

Each of the first n-type semiconductor layer 85 and second n-type semiconductor layer 86 contains an n-type semiconductor crystal formed through epitaxial growth. For example, the first n-type semiconductor layer 85 may contain a 25-nm-thick gallium nitride crystal, and the second n-type semiconductor layer 86 may contain a 400-nm-thick gallium nitride crystal. The first n-type semiconductor layer 85 and the second n-type semiconductor layer 86 may have a group 14 element, such as Si, as a dopant.

The blue light-emitting layer 13, the green light-emitting layer 23, and the red light-emitting layer 33 contain a light-emitting material that emits light in response to an exciton generated as the result of electron-and-hole recombination of electrons from the electron transport layer 4 and holes from the hole transport layer 5. The light-emitting material of the blue light-emitting layer 13, the light-emitting material of the green light-emitting layer 23, and the light-emitting material of the red light-emitting layer 33 emit blue light, green light, and red light, respectively, and these light-emitting materials have a multi-quantum-well structure for instance.

For example, indium gallium nitride (a mixed crystal of In and Ga at an atomic ratio of 1:4) having a thickness of 50 nm, and having an In (indium) composition ratio of 20% can be used as the blue light-emitting layer 13 that emits blue light of wavelength about 450 nm. For example, indium gallium nitride (a mixed crystal) having an In composition ratio of 25% can be used as the green light-emitting layer 23 that emits green light of wavelength about 550 nm. For example, indium gallium nitride (a mixed crystal) having an In composition ratio of 30% can be used as the red light-emitting layer 33 that emits red light of wavelength about 630 nm.

### Electrode of Light-Emitting Element of Display Device

Referring back to FIG. 4, the blue light-emitting element 10, the green light-emitting element 20, and the red light-emitting element 30 respectively include an anode 11, anode 21, and an anode 31. Each anode is electrically connected to the lower surface of the hole transport layer 5 that is closest to the second substrate 7 in the corresponding light-emitting element. Each anode is also electrically connected to the corresponding pixel circuit 71 via the joining material 6 or other things, and the anodes receive voltage individually via the respective pixel circuits 71.

The blue light-emitting element 10, the green light-emitting element 20, and the red light-emitting element 30 respectively include a cathode 12, a cathode 22, and a cathode 32. Each cathode is electrically connected to part of the lower surface of the hole transport layer 5 that is closest to the second substrate 7 in the corresponding light-emitting element. Each cathode is electrically connected to an auxiliary power supply, not shown, via the joining material 6 or other things, and the cathodes receive common voltage.

In this embodiment, the electron transport layer 4 is an n-type semiconductor layer, and the hole transport layer 5 includes an n-type semiconductor layer adjacently to each anode. This reduces the need to make a difference in work function between the material of each anode and the material of each cathode, thereby bringing an advantage to the display device 1; for instance, each anode and each cathode can be made of an identical material. Each anode and each cathode may have a stacked structure of Ti, Al, and Ti for instance.

It is noted that the display device 1 according to this embodiment includes, by way of example, a plurality of blue light-emitting elements 10, a plurality of green light-emitting elements 20, and a plurality of red light-emitting elements 30. For instance, the display device 1 may be a single-color display device including any one kind of light-emitting elements selected from among a plurality of blue light-emitting elements 10, a plurality of green light-emitting elements 20, and a plurality of red light-emitting elements 30.

The display device 1 may also include a wavelength conversion layer in a location that is closer to where light is extracted than each light-emitting element. Here, each of the wavelength conversion layers converts the wavelength of light emitted from the corresponding light-emitting element. For instance, the display device 1 may include a plurality of blue light-emitting elements 10 and may include, as wavelength conversion layers arranged in plan view, green and red conversion layers in locations overlapping some of the plurality of blue light-emitting elements 10 in plan view. Here, the green conversion layer contains a fluorescent material that emits green light, and the red conversion layer contains a fluorescent material that emits red light. Alternatively, the display device 1 may include a plurality of light-emitting elements that emit ultraviolet light. The display device 1 in this case may include, as wavelength conversion layers arranged in plan view, blue, green, and red conversion layers in locations overlapping the respective light-emitting elements in plan view. Here, the blue conversion layer contains a fluorescent material that emits blue light, the green conversion layer contains a fluorescent material that emits green light, and the red conversion layer contains a fluorescent material that emits red light. Accordingly, the display device 1 may be capable of color display while including only a plurality of light-emitting elements of the same emission color.

### Principle of Light Emission of Light-Emitting Element

The display device 1 drives the individual pixel circuits 71 via a driver, not shown, or other things, to thus apply voltage individually to the anodes of the individual light-emitting elements, thereby making a potential difference between the anode and cathode of each light-emitting element. The display device 1 thus injects holes from each anode to the hole transport layer 5, and electrons from each cathode to the electron transport layer 4.

It is noted that the holes from each anode may tunnel through the second n-type semiconductor layer 86 and first n-type semiconductor layer 85 of the hole transport layer 5 and may be then injected into the second p-type semiconductor layer 84. The display device 1 in this case can achieve efficient charge injection from the electrodes of each light-emitting element. The display device 1 extracts light from each light-emitting element by injecting holes and electrons from the electrodes of the light-emitting element into the corresponding light-emitting layer, to thus cause the light-emitting layer to emit light.

It is noted that in the blue light-emitting element 10, electrons from the cathode 12 need to be injected into the blue light-emitting layer 13 by way of the electron transport layer 4 that is directly over the blue light-emitting layer 13; in other words, these electrons do not have to be injected by way of the underlayer 3. It is also noted that in the green light-emitting element 20, electrons from the cathode 22 may be injected into the green light-emitting layer 23 by way of the electron transport layer 4 that is directly over the green light-emitting layer 23; in other words, these electrons do not have to be injected by way of each layer closer to the first substrate 2 than the electron transport layer 4. It is also noted that in the red light-emitting element 30, electrons from the cathode 32 may be injected into the red light-emitting layer 33 by way of the electron transport layer 4 that is directly over the red light-emitting layer 33; in other words, these electrons do not have to be injected by way of each layer closer to the first substrate 2 than the electron transport layer 4.

### Emission Region of Light-Emitting Element

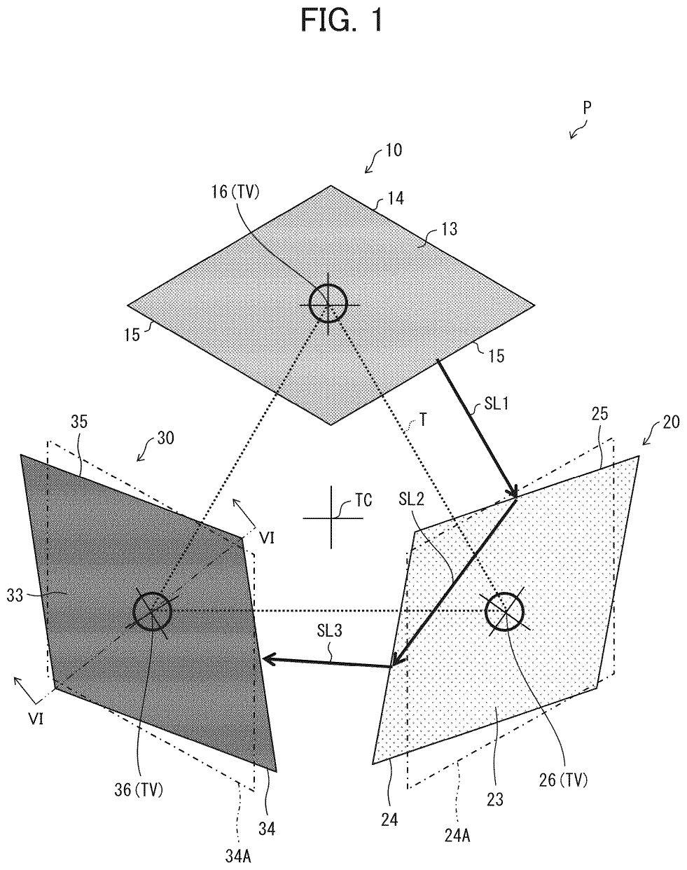

Each light-emitting element in the pixel P of the display device 1 according to this embodiment will be detailed with reference to FIG. 1. FIG. 1 is another enlarged plan view of the display device 1; in particular, FIG. 1 is an enlarged plan view of the pixel P illustrated in FIG. 3. FIG. 1 illustrates the individual light-emitting layers where regions emit light upon driving of the light-emitting elements including their respective light-emitting layers are extracted.

The blue light-emitting element 10, the green light-emitting element 20, and the red light-emitting element 30 respectively have a first emission region 14, a second emission region 24, and a third emission region 34. The first emission region 14, the second emission region 24, and the third emission region 34 each have a quadrangular shape in plan view; in this embodiment in particular, each has a rhombic shape. The first emission region 14, the second emission region 24, and the third emission region 34 thus respectively have four end sides 15, four end sides 25, and four end sides 35 in plan view.

To enlarge each emission region while keeping the distance between two adjacent pixels P, the emission regions included in each pixel P desirably fall within a region whose outer shape in plan view is a substantially regular hexagon. The emission regions included in the pixel P, and each of which has a quadrangular shape in plan view can further form the outer shape of the pixel Pinto a shape that is close to a substantially regular hexagon. Furthermore, to form the outer shape of the pixel Pinto a shape that is close to a substantially regular hexagon, the outer shapes of the individual emission regions included in the pixel P may be a rhombus, a parallelogram, or a trapezoid.

It is noted that the first emission region 14, the second emission region 24, and the third emission region 34 may have an identical shape in plan view in order to simplify a mask pattern during the production of each light-emitting element, and to further facilitate the manufacture of the display device 1. In the present disclosure, the wording “have an identical shape” does not necessarily mean that two components have exactly the same shape; this wording permits differences, such as manufacturing tolerances.

One of the end sides of the emission region of each light-emitting element faces one of the end sides of the emission region of another light-emitting element in plan view. Here, these two sides facing each other extend in a direction where the two sides intersect in plan view, in other words, the two sides are not parallel in plan view. For instance, between the end side 15 and the end side 25, between the end side 25 and the end side 35, and between the end side 35 and the end side 15, two sides facing each other extend in a direction where the two sides intersect in plan view.

The first emission region 14, the second emission region 24, and the third emission region 34 respectively have a center 16, a center 26, and a center 36. In this embodiment, the center of each emission region may coincide with the intersection of two diagonal lines of the emission region in plan view. In the present disclosure, the center of a certain region in plan view is a location where the first-order moment of cross-section stands at zero with this region in plan view defined as a cross-section.

### Positional Relationship Between Emission Regions

To describe the positional relationship between the emission regions in the pixel P, FIG. 1 shows a virtual figure T denoted by dotted lines. The figure T is a regular triangle having a center TC in plan view and has three vertexes TV. The figure T is thus a figure having 3-fold rotational symmetry with respect to the center TC in plan view, and furthermore, the three vertexes TV are in positions that are 3-fold rotationally symmetric with each other with respect to the center TC in plan view.

The centers 16, 26, and 36 in this embodiment coincide with the respective vertexes TV of the figure T in plan view. The centers 16, 26, and 36 are each thus in positions that are 3-fold rotationally symmetric with each other in plan view.

To describe the positional relationship between the emission regions in the pixel P, FIG. 1 also shows a virtual second emission region 24A denoted by dotted lines, and a virtual third emission region 34A denoted by dotted lines. Each of the second emission region 24A and third emission region 34A coincides, in plan view, with the first emission region 14 rotated about a point located outside the first emission region 14, in particular, about the center TC.

Here, the second emission region 24 coincides, in plan view, with a region rotated about a point located inside the second emission region 24A, in particular, about the center of the second emission region 24A. In addition, the third emission region 34 coincides, in plan view, with a region rotated about a point located inside the third emission region 34A, in particular, about the center of the third emission region 34A. Consequently, the display device 1 easily achieves a configuration where two sides facing each other are not parallel in plan view between the end side 15 and the end side 25, and between the end side 15 and the end side 35.

### Reduction of Stray Light

Effects resulting from the positional relationship between the emission regions will be described with reference to FIG. 1.

Light from each light-emitting element of the display device 1 is extracted from the corresponding light-emitting layer toward the first substrate 2 or the second substrate 7 and is then used for display in the display section DA. On the other hand, light from each light-emitting element of the display device 1 includes light emitted from the side surface of the corresponding light-emitting layer, and this light contains a component that propagates from one light-emitting element to another light-emitting element.

For instance, light that propagates from each light-emitting element to a direction parallel to the display surface of a display device is difficult to use for display. Hence, the generation of such light leads to reduction in the efficiency of light extraction from each light-emitting element.

Further, among light rays that propagate from one light-emitting element to another light-emitting element, a light ray that propagates in a direction deviating from a direction parallel to the display surface of a display device is extracted in some cases from a location overlapping the other light-emitting element in plan view. This light is stray light extracted in a location different from a location that is expected to be originally used in extracting the light, and such stray light degrades the display quality of the display device. Furthermore, this stray light can reflect multiply between the light-emitting elements, thereby possibly leading to further degradation in the display quality of the display device.

In this embodiment, two sides facing each other between two adjacent emission regions are not parallel in plan view. Thus, light emitted from the side surface of the light-emitting layer of one light-emitting element is refracted upon entering another light-emitting element. Furthermore, parts of the individual emission regions in this embodiment are in positions that are 3-fold rotationally symmetric in plan view. Hence, such refracted light as described above can be propagated so as to circle between three light-emitting elements including their emission regions parts of which are located, in plan view, in positions that are 3-fold rotationally symmetric with each other in plan view.

FIG. 1 illustrates, by way of example, light SL1 emitted from the side surface of the blue light-emitting layer 13 to the green light-emitting element 20. In this case, the light SL1 entered the green light-emitting element 20 is refracted at the end side 25 of the second emission region 24 to be turned into light SL2, which then propagates through the green light-emitting element 20. Furthermore, the light SL2 is refracted again at another end side 25 of the second emission region 24 to be turned into light SL3, which then propagates to the red light-emitting element 30. By repeating the foregoing, light emitted from the side surface of any one of the light-emitting layers within the pixel P propagates so as to circle within the pixel P in plan view. As such, the display device 1 prevents the foregoing light to be extracted outside the pixel P to be thus turned into stray light.

As described above, the display device 1 according to this embodiment reduces a phenomenon where light emitted from the side surface of the light-emitting layer of a certain light-emitting element is extracted from a location overlapping a distant light-emitting element in plan view. The display device 1 thus reduces occurrence of stray light and improves its display quality. In addition, the display device 1 according to this embodiment relatively increases the intensity of light that travels from each light-emitting layer toward its display surface, thereby improving the efficiency of light extraction from the individual light-emitting elements.

In this embodiment in particular, the center 16, the center 26, and the center 36 are each in positions that are 3-fold rotationally symmetric with each other in plan view. This enables the display device 1 to enhance the rotational symmetry of the positions of the first emission region 14, second emission region 24, and third emission region 34 in plan view, thereby further reducing stray light.

### Relationship Between Side Surface of Light-Emitting Layer and Surface of Substrate

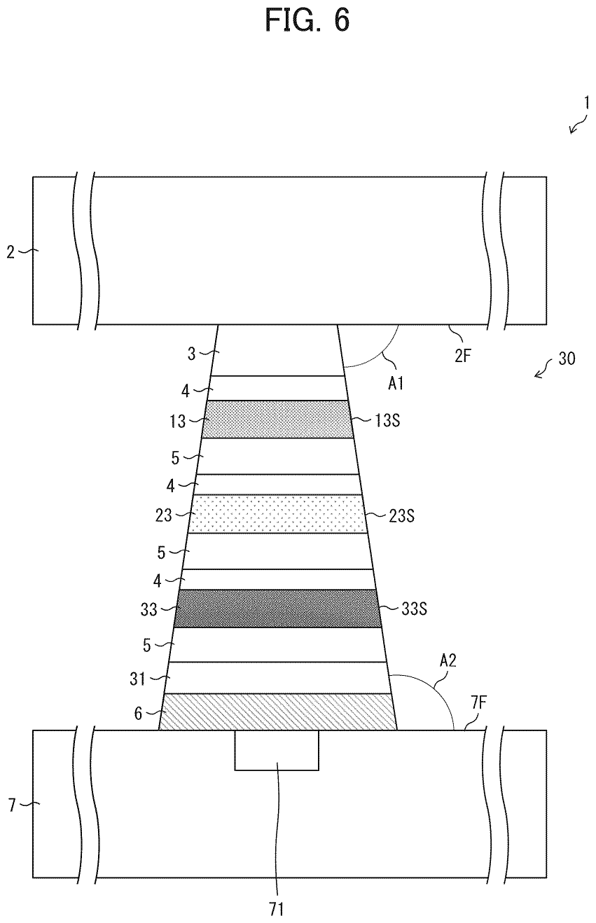

The light-emitting elements according to this embodiment will be further detailed with reference to FIG. 6. FIG. 6 is another schematic sectional side view of the display device 1 according to this embodiment. In particular, FIG. 6 is a sectional view taken along line VI-VI in FIG. 1; in other words, FIG. 6 is a schematic sectional side view of the display device 1 taken along a line passing through the red light-emitting element 30.

The outer side surfaces of the red light-emitting element 30 includes an outer side surface 13S of the blue light-emitting layer 13, an outer side surface 23S of the green light-emitting layer 23, and an outer side surface 33S of the red light-emitting layer 33, which are substantially flush with each other. Here, the outer side surfaces of the red light-emitting element 30 form a first angle A1 together with the first surface 2F of the first substrate 2 and forms a second angle A2 together with the second surface 7F of the second substrate 7.

The red light-emitting element 30 in this embodiment may have a frustum-shaped portion having a distal end adjacently to the first substrate 2. In this case, the first angle A1 is an acute angle at this portion, and the second angle A2 is an obtuse angle at this portion. In other words, the outer side surface 13S, outer side surface 23S, and outer side surface 33S form an acute angle together with the first surface 2F and forms an obtuse angle together with the second surface 7F.

It is noted that the blue light-emitting element 10 and the green light-emitting element 20 have the same configuration as that of the red light-emitting element 30 with the exception that part of each layer adjacent to the second substrate 7 is replaced with the joining material 6. Thus, in the blue light-emitting element 10 and the green light-emitting element 20 as well, the outer side surface of each light-emitting layer forms an acute angle together with the first surface 2F and forms an obtuse angle together with the second surface 7F.

The display device 1 with the foregoing configuration can reduce components of light that is included in light emitted from the outer side surfaces of the individual light-emitting layers, and that propagates in a direction parallel to the first surface 2F or second surface 7F, and the display device 1 thus improves the efficiency of light extraction from the individual light-emitting elements. The display device 1 also reduces a phenomenon where stray light at the outer side surfaces of each light-emitting element, in particular, at the outer side surface of each light-emitting layer propagates to a distant place, thereby improving its display quality.

### Method for Manufacturing Display Device

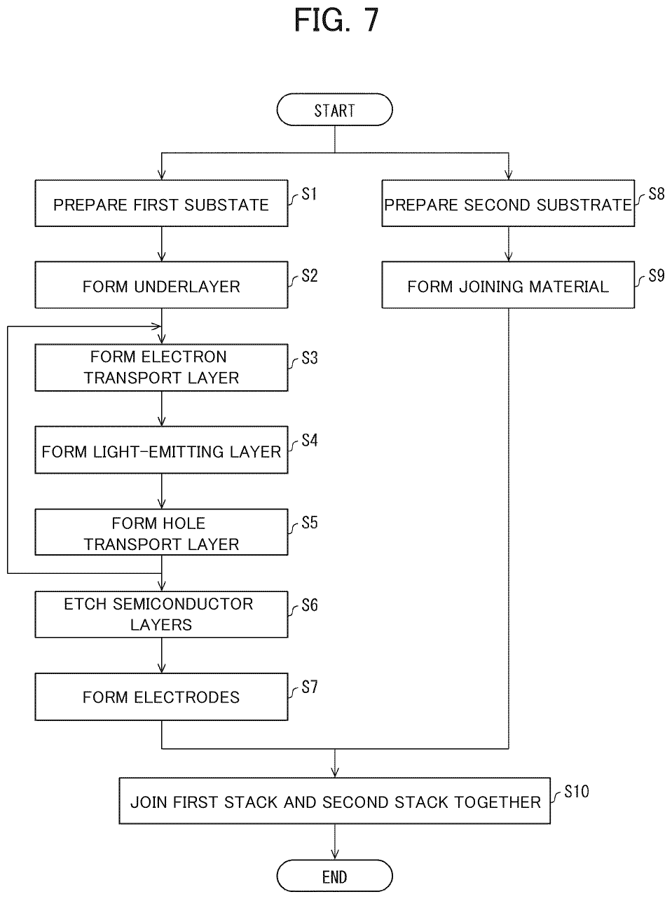

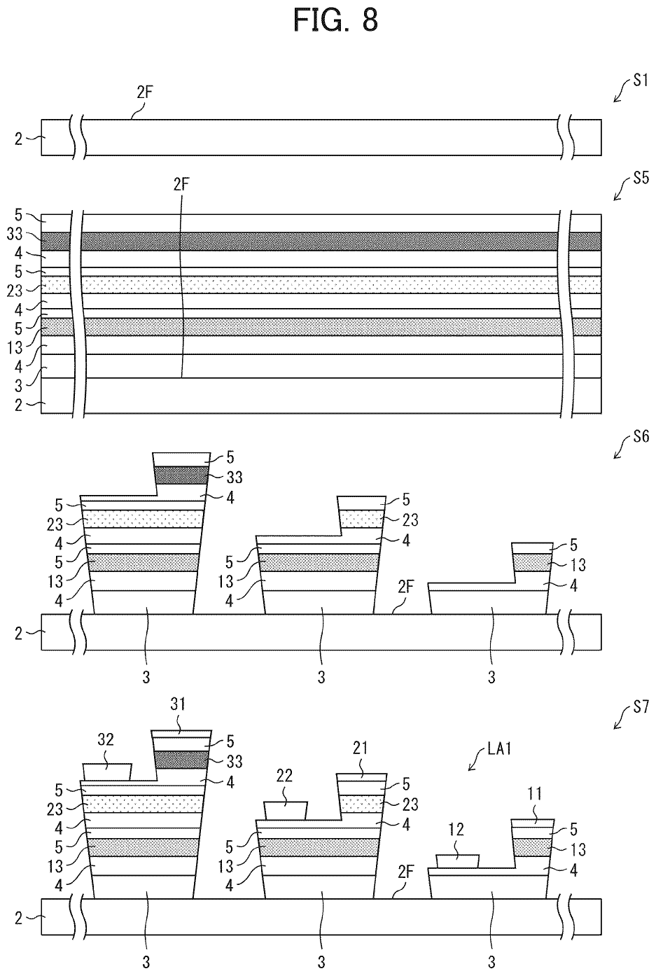

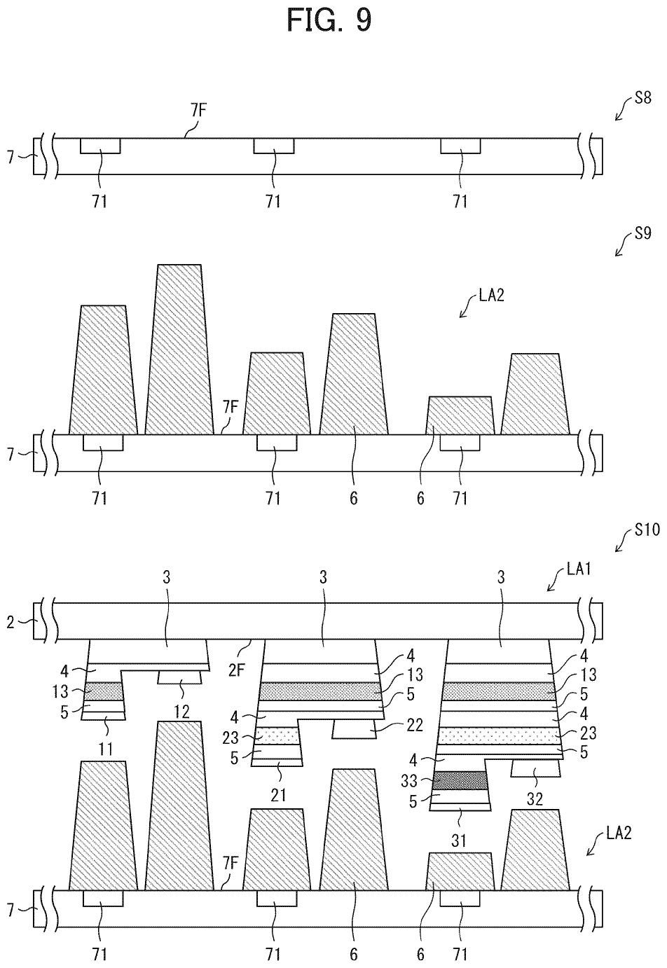

A method for manufacturing the display device 1 according to this embodiment will be described with reference to FIGS. 7 to 9. FIG. 7 is a flowchart showing the method for manufacturing the display device 1. FIGS. 8 and 9 are sectional views of the display device 1 in the process of being manufactured. These process-step sectional views in this embodiment are all sectional views of the display device 1 at a location corresponding to the sectional view of the display device 1 in FIG. 4.

In the method for manufacturing the display device 1, the first process step (Step S1) is preparing the first substrate 2, as shown in FIG. 7. Step S1 is preparing the first substrate 2 with the first surface 2F up. Step S1 may include preparing a large first substrate 2; in this case, the method for manufacturing the display device 1 may include cutting the large first substrate 2 together with the second substrate 7 into individual display devices 1.

The next (Step S2) is forming the underlayer 3 onto the first surface 2F of the first substrate 2, followed by a process step (Step S3) of forming the electron transport layer 4, followed by a process step (Step S4) of forming the light-emitting layers, followed by a process step (Step S5) of forming the hole transport layer 5. Each layer may be formed through the foregoing method. In addition, Steps S3 through S5 may be repeated as many times as the number of light-emitting layers when the display device 1 includes a plurality of light-emitting layers. Accordingly, a stacked structure of a plurality of semiconductor layers are formed onto the first substrate 2, as illustrated in Step S5 in FIG. 8.

The next (Step S6) is etching these semiconductor layers. Step S6 may include etching the semiconductor layers through, for instance, dry etching. Step S6 may be performed by repeating the following: forming a resist; patterning the resist through photolithography; etching the semiconductor layers exposed from the resist in plan view; and removing the resist.

In Step S6, the location where each light-emitting element is to be formed undergoes etching in such a manner that a part of the hole transport layer 5 directly over the light-emitting layer included in this light-emitting element, and a part of the electron transport layer 4 directly under the light-emitting layer are exposed. For instance, the location where the blue light-emitting element 10 is to be formed undergoes etching in such a manner that a part of the hole transport layer 5 directly over the blue light-emitting layer 13, and a part of the electron transport layer 4 directly under the blue light-emitting layer 13 are exposed.

Furthermore, all the semiconductor layers on the first substrate 2 undergo removal between the locations where the respective light-emitting elements are to be formed. Step S6 may include regulating an angle between the end surface of each layer and the first surface 2F, i.e., the first angle A1 by changing conditions of the patterning and etching in removing the semiconductor layers between the locations where the respective light-emitting elements are to be formed. Through the foregoing, the structure illustrated in Step S8 in FIG. 8 is formed. It is noted that the semiconductor layers between the locations where the respective light-emitting elements are to be formed may be removed after the formation of electrodes that will be described later on.

The next (Step S7) is forming electrodes including the anode and cathode of each light-emitting element. For instance, Step S7 is forming a resist pattern in a location including the upper surfaces of the electron transport layer 4 and hole transport layer 5 exposed in Step S6, followed by forming a thin metal film of Ti, Al, and Ti in this order through evaporation or other methods. The next is patterning the formed thin metal film by removing the resist pattern. Through the foregoing, each anode is formed onto the upper surface of the hole transport layer 5 in the location where the corresponding light-emitting element is to be formed, and each cathode is formed onto the upper surface of the electron transport layer 4 in the same, as illustrated in Step S7 in FIG. 8. The foregoing manufacturing method can be performed when the same material is used for the individual anodes and cathodes. In this case, the manufacturing method reduces the need to separately perform the step of forming each anode and the step of forming each cathode, thereby offering a simpler method for manufacturing the display device 1.

The foregoing process steps provide a first stack LA1 with the semiconductor layers and electrodes formed on the first substrate 2. In this embodiment, a process step may be performed thereafter, where a protective layer that covers the side surfaces of the blue light-emitting element 10, green light-emitting element 20, and red light-emitting element 30 on the first substrate 2 is formed.

The method for manufacturing the display device 1 according to this embodiment includes a process step (Step S8) of preparing the second substrate 7, separately from the foregoing formation of the first stack LA1. Step S8 is preparing the second substrate 7 with the second surface 7F up. Step S8 may include forming the pixel circuits 71 onto the second substrate 7.

The next (Step S9) is forming the joining material 6 onto the second surface 7F. The joining material 6 may be formed by, for example, forming a photosensitive resin film, and by patterning the photosensitive resin film through photolithography. In Step S8, the height of each joining material 6 is designed by reflecting the height of each layer formed in the first stack LA1, which is to be attached to a second stack LA2, which will be described later on. Step S8 may include forming a contact portion in the joining material 6 in order to achieve electrical connection between the pixel circuit 71 and the anode, and between an auxiliary electrode and the cathode.

The foregoing process steps provide the second stack LA2 with the joining materials 6 formed on the second substrate 7.

The method for manufacturing the display device 1 according to this embodiment includes, after the completion of Steps S7 and S9, a process step (Step S10) of joining the first stack LA1 and the second stack LA2 together. Step S10 is joining the first stack LA1 and the second stack LA2 together, by, for instance, placing the first surface 2F and the second surface 7F face-to-face, and joining the first substrate 2 and the second substrate 7 together with an adhesive, not shown, or other things. Through the foregoing, the method for manufacturing the display device 1 is completed. It is noted that the first substrate 2 may be removed from the individual light-emitting elements through a laser liftoff method or other methods after the first stack LA1 and the second stack LA2 are joined together.

### Evaluations of Optical Properties of Display Devices

The following describes evaluations of the optical properties of display devices according to an example and comparative examples.

The display device according the example has the same configuration as that of the display device 1 according to this embodiment and is produced through the same method as the foregoing method for manufacturing the display device 1. The display devices according to the comparative examples are the same as the display device 1 according to this embodiment with the exception of the shape of the emission region of each light-emitting element. The emission regions of the display devices according to the comparative examples are rectangular and are arranged in a row-and-column direction in plan view. Further, in the display devices according to the comparative examples, two sides belonging to two respective emission regions adjacent to each other, and facing each other extend substantially parallel.

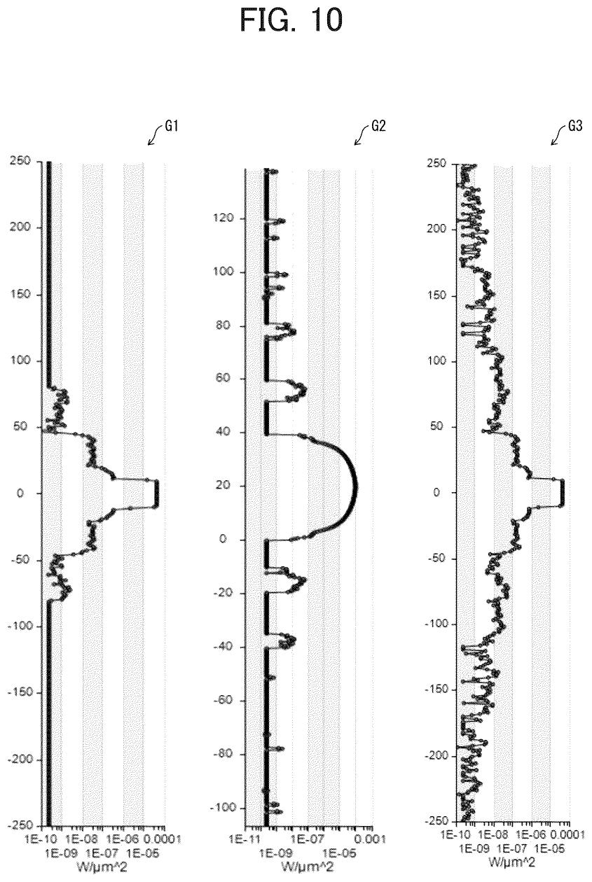

Each of the example and comparative examples underwent luminance measurement at individual locations of the display surface of the display device by causing only any one of the light-emitting elements of the display device to emit light. FIG. 10 is a graph G1 showing the measurement results in the display device according to the example, and graphs G2 and G3 showing the measurement results in the display devices according to the comparative examples. In each of the graphs shown in FIG. 10, the vertical axis represents the distance (in the unit μm) of the emission region included in a target light-emitting element that is caused to emit light, from its center in plan view, and the horizontal axis represents luminance (in the unit W/μm²). The graphs G1 and G2 show the measurement results on a measured surface MA, illustrated in FIG. 4, in the display devices according to the respective example and comparative example, and the graph G3 shows the measurement result on a measured surface MB, illustrated in FIG. 4, in the display device according to the comparative example. The measured surface MA is 200 nm away inwardly from the first surface 2F of the first substrate 2, and the measured surface MA is located at the interface between the first surface 2F of the first substrate 2 and the individual light-emitting elements. It should be noted that the data in each graph shown in FIG. 10 is plotted at a scale capable of presenting the maximum luminance level, and that the scale size of each axis is different from graph to graph.

As clearly seen from the comparisons between the graphs in FIG. 10, when compared to the display devices according to the comparative examples, the display device according to the example is configured such that its luminance is high near the center of the emission region of the target light-emitting element, and that the luminance sharply lowers in a location that is about 10 μm away from the center. Furthermore, when compared to the display devices according to the comparative examples, the display device according to the example can have little luminance in a location that is 100 μm or greater away from the center. These comparisons to the display devices according to the comparative examples reveal that the display device according to the example reduces stray light extraction in a location that is away from the emission region of the target light-emitting element.

### Second Embodiment

### Modification of Shape of Emission Region

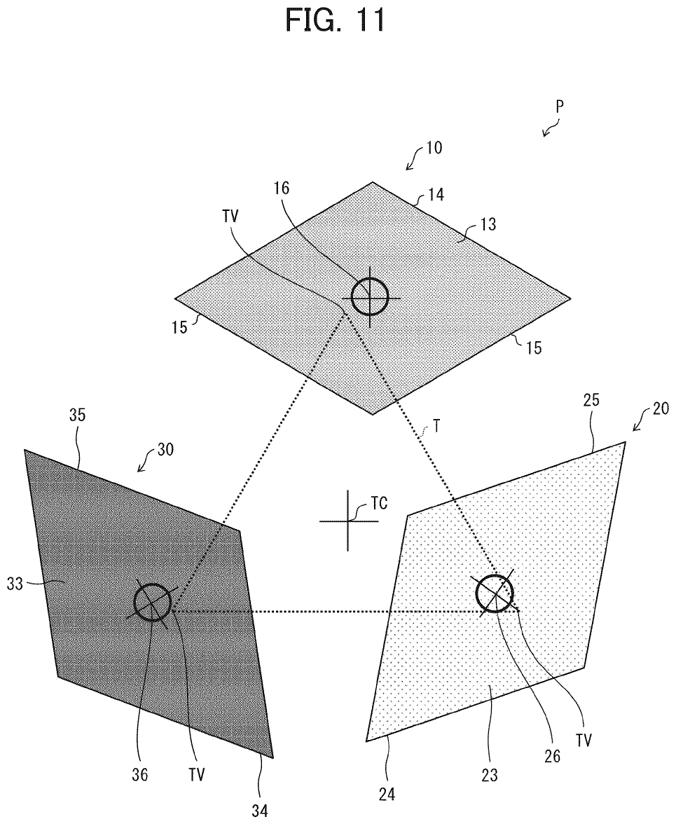

A display device according to another embodiment will be described with reference to FIG. 11. FIG. 11 is an enlarged plan view of the display device 1 according to this embodiment and is an enlarged view of a region that is the same as the region illustrated in FIG. 1.

The display device 1 according to this embodiment has the same configuration as that of the display device 1 according to the foregoing embodiment with the exception of the locations for forming the respective light-emitting elements. In this embodiment in particular, the center 16, the center 26, and the center 36 are in locations different from the vertexes TV of the figure T in plan view. However, each vertex TV of the figure T coincides with a part of a corresponding one of the first emission region 14, second emission region 24, and third emission region 34 in plan view. The display device 1 according to this embodiment can be manufactured through the method for manufacturing the display device 1 according to the foregoing embodiment with a modification made to the location for etching the semiconductor layers in Step S6.

As such, the display device 1 according to this embodiment is configured such that any part of the first emission region 14, any part of the second emission region 24, and any part of the third emission region 34 are in positions that are 3-fold rotationally symmetric with each other. Accordingly, the display device 1 according to this embodiment reduces stray light propagation between the light-emitting elements and thus improves its display quality for the same reason as the reason described in the foregoing embodiment.

### Third Embodiment

### Modification of Shape of Light-Emitting Element

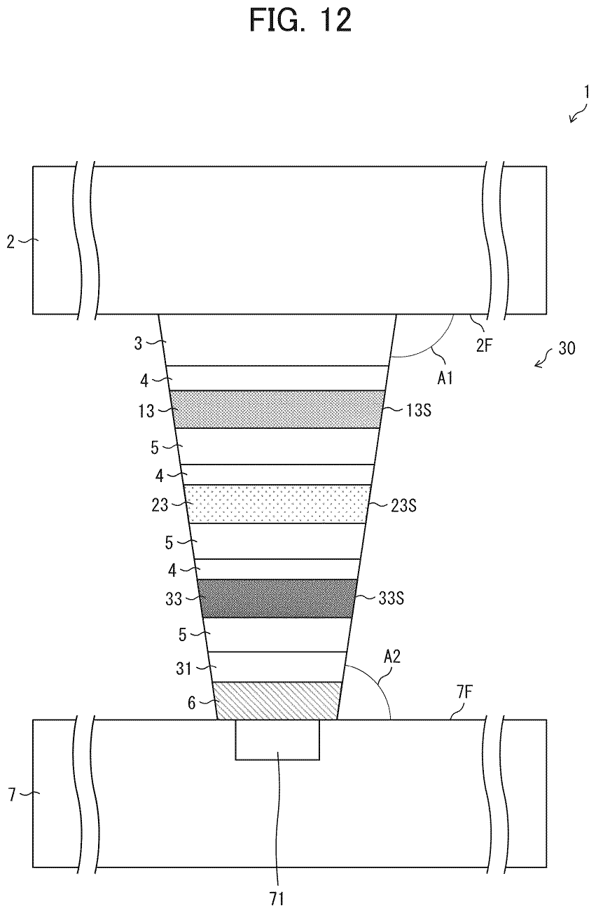

A display device according to another embodiment will be described with reference to FIG. 12. FIG. 12 is a schematic sectional side view of the display device 1 according to this embodiment and is a sectional side view in a location that is the same as that in the sectional side view illustrated in FIG. 6.

The display device 1 according to this embodiment has the same configuration as that of the display device 1 according to the foregoing embodiment with the exceptions that the first angle A1 is an obtuse angle, and that the second angle A2 is an acute angle. Each light-emitting element of the display device 1 according to this embodiment may have a frustum shape having a distal end adjacently to the first substrate 7. The display device 1 according to this embodiment can be manufactured through the method for manufacturing the display device 1 according to the foregoing embodiment with modifications made to the condition for etching the semiconductor layers in Step S6, and to the condition for forming the joining material 6 in Step S9. The display device 1 according to this embodiment improves the efficiency of light extraction from the individual light-emitting elements and reduces the propagation of stray light on the outer side surface of each light-emitting layer to a distant place, thereby improving its display quality.

### Fourth Embodiment

### Asperities on Emission Region

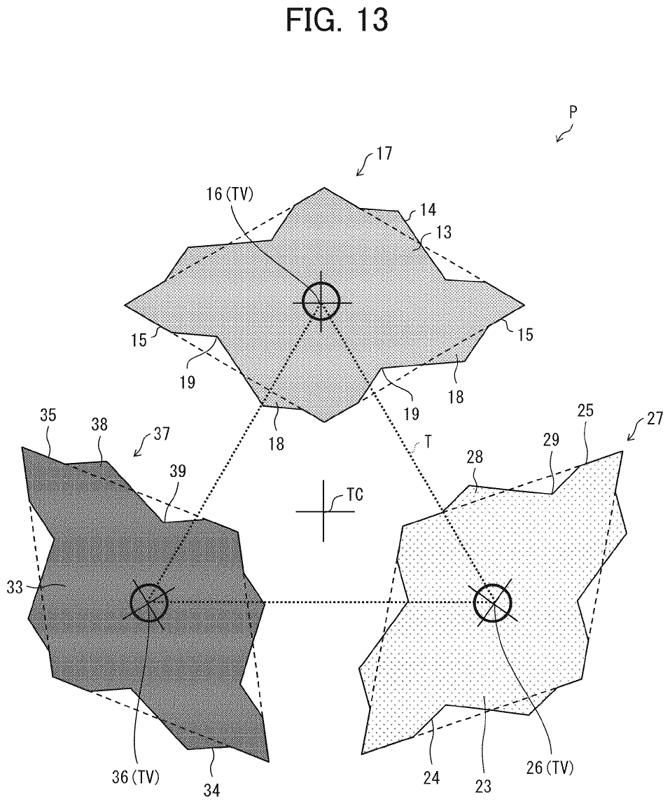

A display device according to another embodiment will be described with reference to FIG. 13. FIG. 13 is an enlarged plan view of the display device 1 according to this embodiment and is an enlarged view of a region that is the same as the region illustrated in FIG. 1.

The display device 1 according to this embodiment has the same configuration as that of the display device 1 according to the foregoing embodiment with the exception of the shape of the emission region of each light-emitting element in plan view. The emission region of any one of the light-emitting elements according to this embodiment has at least one of a protrusion protruding more outward than the surrounding part in plan view, and a recess recessed more inward than the surrounding part in plan view.

For instance, the first emission region 14 has a protrusion 18 and a recess 19, the second emission region 24 has a protrusion 28 and a recess 29, and the third emission region 34 has a protrusion 38 and a recess 39, as illustrated in FIG. 13. The display device 1 according to this embodiment can be manufactured through the method for manufacturing the display device 1 according to the foregoing embodiment with a modification made to the location for etching the semiconductor layers in Step S6.

It is noted that the end sides of each emission region in this embodiment are each on a line connecting together the vertexes of the emission region in plan view. Thus, in this embodiment, between the end side 15 and the end side 25, between the end side 25 and the end side 35, and between the end side 35 and the end side 15, two sides facing each other extend in a direction where the two sides intersect in plan view. Accordingly, the display device 1 according to this embodiment reduces stray light propagation between the light-emitting elements and thus improves its display quality for the same reason as the foregoing reason.

Furthermore, each emission region according to this embodiment has a recess and a protrusion. Accordingly, the display device 1 according to this embodiment is configured such that the side surfaces belonging to two respective light-emitting layers adjacent to each other, and facing each other extend in a further different direction. The display device 1 according to this embodiment consequently further reduces stray light propagation between the light-emitting elements and thus further improves its display quality for the same reason as the foregoing reason.

### Fifth Embodiment

### Modification of Arrangement of Light-Emitting Elements

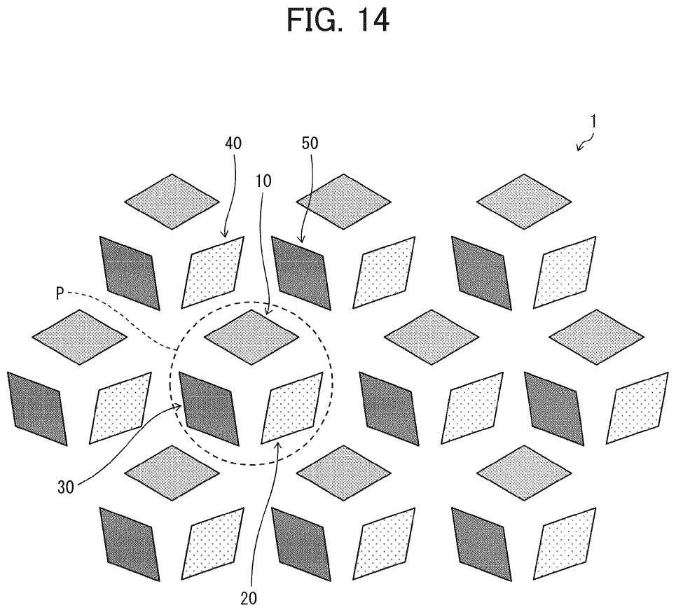

A display device according to another embodiment will be described with reference to FIG. 14. FIG. 14 is an enlarged plan view of the display device 1 according to this embodiment and is an enlarged view of a region that is the same as the region illustrated in FIG. 3.

The display device 1 according to this embodiment has a configuration different from that of the display device 1 according to the foregoing embodiment with the exception of how to arrange the individual light-emitting elements. In particular, the display device 1 according to this embodiment is configured such that the positional relationship in plan view between the blue light-emitting element 10, green light-emitting element 20, and red light-emitting element 30 is the same among all the pixels P. The display device 1 according to this embodiment can be manufactured through the method for manufacturing the display device 1 according to the foregoing embodiment with a modification made to the location for etching the semiconductor layers in Step S6.

However, the blue light-emitting element 10 in this embodiment is adjacent to the green light-emitting element 20 and red light-emitting element 30 included in the pixel P including the blue light-emitting element 10. The blue light-emitting element 10 is also adjacent to the green light-emitting element 40 and red light-emitting element 50 included in the pixel P different from the pixel P including the blue light-emitting element 10. Furthermore, the individual light-emitting elements in this embodiment are arranged in such a manner that the color of emitted light is different between two of the light-emitting elements adjacent to each other. Accordingly, the emission regions of the two adjacent light-emitting elements are coupled together apparently; consequently, the display device 1 prevents degradation in its display quality that results from substantial resolution reduction.

### Sixth Embodiment

### Wearable Device

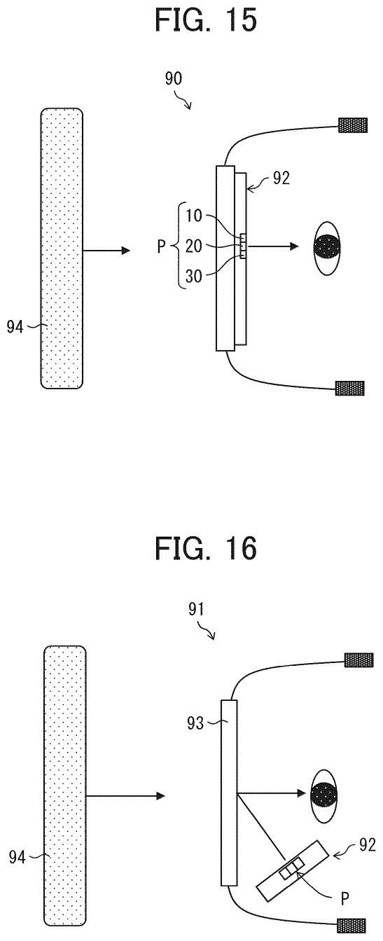

FIGS. 15 and 16 are schematic sectional views of examples of the configuration of a wearable device according to this embodiment. Each of a wearable device 90 illustrated in FIG. 15 and a wearable device 91 illustrated in FIG. 16 includes a light-emitting device 92. The light-emitting device 92 has a plurality of pixels P according to each of the foregoing embodiments, and each pixel P includes the blue light-emitting element 10, green light-emitting element 20, and red light-emitting element 30 according to each of the foregoing embodiments.

Each of the wearable device 90 and wearable device 91 is attachable to a body, another device, or other things. In the wearable device 90, light from the pixel P may enter human eyes, a sensor, or other things as it is, as illustrated in FIG. 15. In the wearable device 91, light from the pixel P may enter human eyes, a sensor, or other things via a projection object 93, as illustrated in FIG. 16. Each of the wearable device 90 and wearable device 91 can superimpose an outside world 94 on a video image formed by the light-emitting device 92.

### SUMMARY

A display device according to a first aspect of the present disclosure includes the following: a first light-emitting element having a first emission region; a second light-emitting element adjacent to the first light-emitting element, and having a second emission region; and a third light-emitting element adjacent to both of the first light-emitting element and the second light-emitting element, and having a third emission region. In a plan view, any part of the first emission region, any part of the second emission region, and any part of the third emission region are in positions that are 3-fold rotationally symmetric with each other. Between the first emission region and the second emission region, between the second emission region and the third emission region, and between the third emission region and the first emission region, two sides facing each other in the plan view extend in a direction where the two sides intersect.

The display device according to a second aspect of the present disclosure may be configured in the first aspect such that the center of the first emission region, the center of the second emission region, and the center of the third emission region are in positions that are 3-fold rotationally symmetric with each other.

The display device according to a third aspect of the present disclosure may be configured in the first or second aspect such that the first emission region, the second emission region, and the third emission region have an identical shape in the plan view.

The display device according to a fourth aspect of the present disclosure may be configured in the third aspect such that at least one of the first emission region, the second emission region, and the third emission region coincides with another emission region rotated about the outside of the another emission region, and rotated about the inside of the another emission region that has been rotated, the another emission region being any one of the first emission region, the second emission region, and the third emission region, and being different from the at least one of the first emission region, the second emission region, and the third emission region.

The display device according to a fifth aspect of the present disclosure may be configured in any one of the first to fourth aspects such that each of the first emission region, the second emission region, and the third emission region has a quadrangular shape in the plan view.

The display device according to a sixth aspect of the present disclosure may be configured in the fifth aspect such that each of the first emission region, the second emission region, and the third emission region is any one of a rhombus, a parallelogram, and a trapezoid.

The display device according to a seventh aspect of the present disclosure may be configured in any one of the first to sixth aspects such that the first light-emitting element includes a first light-emitting layer, such that the second light-emitting element includes a second light-emitting layer, and such that the third light-emitting element includes a third light-emitting layer.

The display device according to an eighth aspect of the present disclosure may include, in the seventh aspect, a first substrate on which the first light-emitting element, the second light-emitting element, and the third light-emitting element are located.

The display device according to a ninth aspect of the present disclosure may be configured in the eighth aspect such that a first angle formed by a first surface of the first substrate and the side surface of any one of the first light-emitting layer, the second light-emitting layer, and the third light-emitting layer is an acute angle or an obtuse angle, the first surface being adjacent to the first light-emitting element, the second light-emitting element, and the third light-emitting element.

The display device according to a tenth aspect of the present disclosure may be configured in the eighth or ninth aspect such that a distance from a first surface of the first substrate is different between at least two of the first light-emitting layer, the second light-emitting layer, and the third light-emitting layer, the first surface being adjacent to the first light-emitting element, the second light-emitting element, and the third light-emitting element.

The display device according to an eleventh aspect of the present disclosure may include, in any one of the seventh to tenth aspects, a second substrate joined with each of the first light-emitting element, the second light-emitting element, and the third light-emitting element via a joining material.

The display device according to a twelfth aspect of the present disclosure may be configured in the eleventh aspect such that a second angle formed by a second surface of the second substrate and the side surface of any one of the first light-emitting layer, the second light-emitting layer, and the third light-emitting layer is an acute angle or an obtuse angle, the second surface being adjacent to the joining material.

The display device according to a thirteenth aspect of the present disclosure may be configured in the eleventh or twelfth aspect such that the second substrate includes a pixel circuit configured to drive each of the first light-emitting element, the second light-emitting element, and the third light-emitting element.

The display device according to a fourteenth aspect of the present disclosure may be configured in any one of the eleventh to thirteenth aspects such that a distance from a second surface of the second substrate is different between at least two of the first light-emitting layer, the second light-emitting layer, and the third light-emitting layer, the second surface being adjacent to the joining material.

The display device according to a fifteenth aspect of the present disclosure may be configured in any one of the first to fourteenth aspects such that in the plan view, at least one of the first emission region, the second emission region, and the third emission region has at least one of a protrusion protruding more outward than a surrounding part in the plan view, and a recess recessed more inward than the surrounding part in the plan view.

The display device according to a sixteenth aspect of the present disclosure may be configured in any one of the first to fifteenth aspect such that the first light-emitting element is configured to emit first light, such that the second light-emitting element is configured to emit second light having a wavelength different from a wavelength of the first light, and such that the third light-emitting element is configured to emit third light having a wavelength different from both of the wavelength of the first light and the wavelength of the second light.

The display device according to a seventeenth aspect of the present disclosure may include the following in the sixteenth aspect: a fourth light-emitting element adjacent to the first light-emitting element in the plan view, and configured to emit the second light; and a fifth light-emitting element adjacent to the first light-emitting element in the plan view, and configured to emit the third light.

The display device according to an eighteenth aspect of the present disclosure may be configured in the sixteenth or seventeenth aspect such that the first light is blue light, such that the second light is green light, and such that the third light is red light.

The display device according to a nineteenth aspect of the present disclosure may be configured in any one of the first to eighteenth aspects such that the display device is a wearable device including a light-emitting device including the first light-emitting element, the second light-emitting element, and the third light-emitting element.

The present disclosure is not limited to the foregoing embodiments. Various modifications can be made within the scope of the claims. An embodiment that is obtained in combination as appropriate with the technical means disclosed in the respective embodiments is also included in the technical scope of the present invention. Furthermore, combining the technical means disclosed in the respective embodiments can form a new technical feature.

While there have been described what are at present considered to be certain embodiments of the invention, it will be understood that various modifications may be made thereto, and it is intended that the appended claim cover all such modifications as fall within the true spirit and scope of the invention.

What is claimed is:

1. A display device comprising:
a first light-emitting element having a first emission region;
a second light-emitting element adjacent to the first light-emitting element, and having a second emission region; and
a third light-emitting element adjacent to both of the first light-emitting element and the second light-emitting element, and having a third emission region,
wherein in a plan view, any part of the first emission region, any part of the second emission region, and any part of the third emission region are in positions that are 3-fold rotationally symmetric with each other, and
between the first emission region and the second emission region, between the second emission region and the third emission region, and between the third emission region and the first emission region, two sides facing each other in the plan view extend in a direction where the two sides intersect.

2. The display device according to claim 1, wherein a center of the first emission region, a center of the second emission region, and a center of the third emission region are in positions that are 3-fold rotationally symmetric with each other.

3. The display device according to claim 1, wherein the first emission region, the second emission region, and the third emission region have an identical shape in the plan view.

4. The display device according to claim 3, wherein at least one of the first emission region, the second emission region, and the third emission region coincides with another emission region rotated about an outside of the another emission region, and rotated about an inside of the another emission region that has been rotated, the another emission region being any one of the first emission region, the second emission region, and the third emission region, and being different from the at least one of the first emission region, the second emission region, and the third emission region.

5. The display device according to claim 1, wherein each of the first emission region, the second emission region, and the third emission region has a quadrangular shape in the plan view.

6. The display device according to claim 5, wherein each of the first emission region, the second emission region, and the third emission region is any one of a rhombus, a parallelogram, and a trapezoid.

7. The display device according to claim 1, wherein
the first light-emitting element includes a first light-emitting layer,
the second light-emitting element includes a second light-emitting layer, and
the third light-emitting element includes a third light-emitting layer.

8. The display device according to claim 7, comprising a first substrate on which the first light-emitting element, the second light-emitting element, and the third light-emitting element are located.

9. The display device according to claim 8, wherein a first angle formed by a first surface of the first substrate and a side surface of any one of the first light-emitting layer, the second light-emitting layer, and the third light-emitting layer is an acute angle or an obtuse angle, the first surface being adjacent to the first light-emitting element, the second light-emitting element, and the third light-emitting element.

10. The display device according to claim 8, wherein a distance from a first surface of the first substrate is different between at least two of the first light-emitting layer, the second light-emitting layer, and the third light-emitting layer, the first surface being adjacent to the first light-emitting element, the second light-emitting element, and the third light-emitting element.

11. The display device according to claim 7, comprising a second substrate joined with each of the first light-emitting element, the second light-emitting element, and the third light-emitting element via a joining material.

12. The display device according to claim 11, wherein a second angle formed by a second surface of the second substrate and a side surface of any one of the first light-emitting layer, the second light-emitting layer, and the third light-emitting layer is an acute angle or an obtuse angle, the second surface being adjacent to the joining material.

13. The display device according to claim 11, wherein the second substrate includes a pixel circuit configured to drive each of the first light-emitting element, the second light-emitting element, and the third light-emitting element.

14. The display device according to claim 11, wherein a distance from a second surface of the second substrate is different between at least two of the first light-emitting layer, the second light-emitting layer, and the third light-emitting layer, the second surface being adjacent to the joining material.

15. The display device according to claim 1, wherein in the plan view, at least one of the first emission region, the second emission region, and the third emission region has at least one of a protrusion protruding more outward than a surrounding part in the plan view, and a recess recessed more inward than the surrounding part in the plan view.

16. The display device according to claim 1, wherein
the first light-emitting element is configured to emit first light,
the second light-emitting element is configured to emit second light having a wavelength different from a wavelength of the first light, and
the third light-emitting element is configured to emit third light having a wavelength different from both of the wavelength of the first light and the wavelength of the second light.

17. The display device according to claim 16, comprising:
a fourth light-emitting element adjacent to the first light-emitting element in the plan view, and configured to emit the second light; and
a fifth light-emitting element adjacent to the first light-emitting element in the plan view, and configured to emit the third light.

18. The display device according to claim 16, wherein
the first light is blue light,
the second light is green light, and
the third light is red light.

19. The display device according to claim 1, wherein the display device is a wearable device comprising a light-emitting device including the first light-emitting element, the second light-emitting element, and the third light-emitting element.

20. The display device according to claim 2, wherein the first emission region, the second emission region, and the third emission region have an identical shape in the plan view.
